(19) United States
(12) Patent Application Publication
(10) Pub. No.: US 2020/0395969 A1
(43) Pub. Date: Dec. 17, 2020

(54) DYNAMICALLY ADAPTABLE MULTIPURPOSE DATA ACQUISITION SYSTEM

(71) Applicant: ISRAEL AEROSPACE INDUSTRIES LTD., Lod (IL)

(72) Inventor: Meir Vardi, Moshav Netaim (IL)

(21) Appl. No.: 16/761,438

(22) PCT Filed: Oct. 24, 2018
(86) PCT No.: PCT/IL2018/051132

§ 371 Date: May 4, 2020

(30) Foreign Application Priority Data
Nov. 5, 2017 (IL) 255437

(51) Int. Cl. H04B 1/16; H01Q 1/28; H01Q 3/30; G01S 13/02; H03F 3/19; B64C 39/02

(52) U.S. Cl. CPC H04B 1/16; H01Q 1/28; H01Q 3/30; H04N 5/23229; H03F 3/19; B64C 39/024; G01S 13/02

(57) ABSTRACT

The presently disclosed subject matter includes a dynamically adaptable data acquisition system. The disclosed system comprises a receiver-processor module operatively connected to at least two antennas, each antenna configured and operable to obtain a respective type of data. Different data types can differentiate for example in the frequency range of the transmitted signals. The disclosed system is multipurpose as it is configured and operable to be switched between a plurality of different operational modes, wherein in each operational mode, the receiver-processor module operates for receiving and processing a certain type of data, received from a different antenna and thereby implement a certain type of data acquisition device. The system is designed such that same components (e.g., amplifiers, converters, processors, controllers, etc.) are shared (also referred to herein as “shared components”) in various operational modes to thereby reduce its size and weight.

### FIELD OF THE PRESENTLY DISCLOSED SUBJECT MATTER

The presently disclosed subject matter relates to remote data acquisition devices and systems and false data transmission devices and systems.

### BACKGROUND

Various types of data acquisition systems (or devices) are available today, where different types are dedicated for obtaining different types of data. Such systems include for example, electro optic (EO) systems (e.g. visible and IR cameras), RADARs and SIGINT collection systems.

SIGINT collection systems, are systems dedicated for intelligence gathering by intercepting signals emitted by other entities (e.g. communication stations or vehicles). SIGINT collection systems are configured to analyze communication signals, and to identify and intercept specific signals of interest. Signal interception enables to obtain information with respect to the transmitted data and the transmitting entity.

Communication intelligence (COMINT) is a sub-category of SIGINT that pertains to messages or voice information derived from interception of communication signals. Electronic intelligence (ELINT) is another sub-category of SIGINT that includes non-communication electromagnetic radiation emanating from various emitters. For examples, geo-location of ships and aircrafts can be determined based on the interception and analysis of their radar transmission and other electromagnetic radiation emanating from their bodies.

Each type of data acquisition system has its own dedicated design comprising specific hardware and software components adapted for obtaining the respective data. For example, EO systems include an optical assembly and image sensors, RADRARs include transmitters, receivers, signal amplifiers, and one or more antennas, and SIGINT collection systems are equipped with certain types of antennas, designed for receiving signals in a certain frequency band according to the SIGINT type which is being implemented (e.g. COMINT/ELINT) and the respective type of data which is being sought.

### GENERAL DESCRIPTION

Different data acquisition systems are characterized by a dedicated design and specific components adapted for enabling the acquisition of a specific type of data. Thus, a dedicated data acquisition system is needed for acquiring each type of data. For example, in order to use the same mobile platform (e.g. an aircraft) for collecting different types of data, a plurality of data acquisition systems, each designated for collecting a specific type of data, is needed to be mounted and operated from the mobile platform. Each system comprises various components which are needed for its operation and are used by that system alone. Such components include for example: various narrow band antennas (or antenna arrays), dedicated amplifiers, dedicated filters, dedicated processors, dedicated up/down converters, dedicated controllers, etc.

Furthermore, according to the common operational paradigm, data acquisition systems are fabricated with the capability to operate while positioned at a large distance (e.g. between tens to hundreds of kilometers) from the target (a signal emitting entity e.g. data transmitting unit or device) and therefore an effort is made to increase the reception and transmission gain of such systems. Accordingly, some data acquisition systems comprise high power components (e.g. one or more high gain and narrow band directional antennas and high power signal amplifiers), which are characterized by significant weight

As a result of the above data acquisition systems are bulky (have large volume), characterized by a high weight (e.g. between tens to hundreds of kilograms) and have a high price tag. Due to the size and weight of such data acquisition systems they can only be carried by medium to large carrying platforms (e.g. large aircrafts, manned or unmanned characterized by a maximal takeoff weight above hundreds of kilograms in some cases 500 kilogram or more). The need to use medium to large carrying platforms further increases the overall system price and the operational costs of such data acquisition system. These problems intensifies when it is desired to activate more than one data acquisition device from the same platform.

The presently disclosed subject matter includes a dynamically adaptable data acquisition system. The disclosed system comprises a receiver-processor module operatively connected to at least two antennas, each antenna configured and operable to obtain a respective type of data. Different data types can differentiate for example in the frequency range of the transmitted signals. The disclosed system is multipurpose as it is configured and operable to be switched between a plurality of different operational modes, wherein in each operational mode, the receiver-processor module operates for receiving and processing a certain type of data, received from a different antenna and thereby implement a certain type of data acquisition device. The system is designed such that same components (e.g., amplifiers, converters, processors, controllers, etc.) are shared (also referred to herein as “shared components”) in various operational modes to thereby reduce its size and weight.

According to one aspect of the presently disclosed subject matter there is provided a system comprising a dynamically adaptable multipurpose data acquisition sub-system comprising:

at least two antennas, each antenna is configured to receive and/or transmit different type of data signals; a shared amplifier operatively connected to the at least two antennas and to a shared receiver-processor module, and configured to amplify data signals received by any one of the at least two antennas;
the shared receiver-processor module comprises at least one processor operatively connected to a plurality of different processing modules; each processing module is configured and operable to process amplified data received by a respective antenna from the at least two antennas;

a main processing unit configured and operable to control switching executed by a shared switching circuitry; the shared switching circuitry is configured and operable, responsive to a switching command, received from the main processing unit, to switch between operational modes, wherein in each operational mode, a processing channel connecting between a certain processing module in the shared receiver-processor module, the shared amplifier and a respective antenna, is selected for processing amplified data of a certain data type, received by the respective antenna to thereby implement a respective data acquisition system.

In addition to the above features, the system according to this aspect of the presently disclosed subject matter can optionally comprise one or more of features (i) to (xiii) below, in any technically possible combination or permutation:

i. The system further comprises a mobile platform configured and operable to carry the sub-system to a target destination.

ii. wherein the mobile platform is an unmanned aerial platform.

iii. wherein the unmanned aerial platform is characterized by a maximal takeoff weight of 50 kilogram or less.

iv. wherein the unmanned aerial platform weighs between 25 to 35 kilograms.

v. wherein the sub-system further comprises a control unit; the control unit is configured and operable to control the operation of the system, and wherein the switching command is transmitted over a communication link from the control unit and received by the main processing unit.

vi. wherein the sub-system further comprises switching logic, wherein the switching command is autonomously generated based on the switching logic.

vii. wherein in each processing channel the respective antenna is connected to the shared amplifier, to thereby enable usage of the same amplifier in all processing modes.

viii. wherein in each processing channel the respective antenna is connected to a shared analog to digital (for example an ultrafast sampling devise), to thereby enable usage of the same converter or sampling device devise in all modes.

ix. wherein the sub-system comprise at least three antennas comprising: at least two Omni-antennas, each antenna configured to operate in a different frequency range, and a phased array RADAR antenna.

x. wherein the at least two antennas covers all the frequency band required for collecting or transmitting communication data and for collecting or transmitting RADARs data.

xi. wherein the at least two antennas are characterized by a gain value around 0 dB and power of 10 Watt or less.

xii. wherein the switching circuitry is configured and operable to switch between reception operational mode and transmission operational mode; wherein in transmission operational mode, a processing channel connecting a processing module in the receiver-processor module to the amplifier and amplifier to a respective antenna is selected by switching circuitry to provide amplified transmitted signals; the processing module is configured and operable to generate signals of a certain frequency range.

xiii. The system further comprises an electro optic sensor operatively connected to a respective processing module configured and operable to process images captured by the electro optic sensor.

According to another aspect of the presently disclosed subject matter there is provided a dynamically adaptable multipurpose data acquisition system comprising:

at least two antennas, each antenna is configured to receive and/or transmit different type of data signals; a shared amplifier operatively connected to the at least two antennas and to a shared receiver-processor module, and configured to amplify data signals received by any one of the at least two antennas;
the shared receiver-processor module comprises at least one processor operatively connected to a plurality of different processing modules; each processing module is configured and operable to process amplified data received by a respective antenna from the at least two antennas;

a main processing unit configured and operable to control switching executed by a shared switching circuitry; the shared switching circuitry is configured and operable, responsive to a switching command, received from the main processing unit, to switch between operational modes, wherein in each operational mode, a processing channel connecting between a certain processing module in the shared receiver-processor module, the shared amplifier and a respective antenna, is selected for processing amplified data of a certain data type, received by the respective antenna to thereby implement a respective data acquisition system.

According to another aspect of the presently disclosed subject matter there is provided an unmanned aerial platform comprising a dynamically adaptable multipurpose data acquisition system comprising:

at least two antennas, each antenna is configured to receive and/or transmit different type of data signals; a shared amplifier operatively connected to the at least two antennas and to a shared receiver-processor module, and configured to amplify data signals received by any one of the at least two antennas;
the shared receiver-processor module comprises at least one processor operatively connected to a plurality of different processing modules; each processing module is configured and operable to process amplified data received by a respective antenna from the at least two antennas;

a main processing unit configured and operable to control switching executed by a shared switching circuitry; the shared switching circuitry is configured and operable, responsive to a switching command, received from the main processing unit, to switch between operational modes, wherein in each operational mode, a processing channel connecting between a certain processing module in the shared receiver-processor module, the shared amplifier and a respective antenna, is selected for processing amplified data of a certain data type, received by the respective antenna to thereby implement a respective data acquisition system;

wherein the unmanned aerial t platform is characterize by a take Off weight between 20 to 50 kilograms.

In addition to the above features, the platform according to this aspect of the presently disclosed subject matter can optionally comprise one or more of features (i) to (iv) below, in any technically possible combination or permutation:

i. The platform of claim 16 is characterize by a weight between 25 to 30 kilograms.

ii. The platform of any one of claims 16 to 17, wherein the at least two antennas include at least a first antenna for collecting COMINT data and a second antenna for collecting ELINT data.

iii. The platform of claim any one of claims 16 to 18, wherein the at least two antennas further include an antenna of a phased array RADAR.

iv. The platform of any one of the claims 16 to 19, wherein the at least two antennas include at least one antenna characterized by a gain value around 0 dB and power of 10 Watt or less.

According to another aspect of the presently disclosed subject matter there is provided a method of operating the dynamically adaptable multipurpose data acquisition system disclosed herein.

The method includes for way of non-limiting example the following operations: while the unmanned aerial platform is airborne:

operating the system in a first operational mode where a first sensor device is connected to a respective processing module in the processing module to thereby obtain a first type of data;

responsive to a received switching command, operating the switching circuitry for switching to a second operational mode where a second sensor device is connected to a respective processing module in the processing module to thereby obtain a second type of data.

The presently disclosed subject matter further contemplates a non-transitory program storage device readable by a computer, for executing operations as disclosed herein.

Any one of the aspects mentioned above can comprise one or more of features mentioned above, mutatis mutandis, in any technically possible combination or permutation.

### BRIEF DESCRIPTION OF THE DRAWINGS

In order to understand the presently disclosed subject matter and to see how it may be carried out in practice, the subject matter will now be described, by way of non-limiting examples only, with reference to the accompanying drawings, in which:

FIG. 1 is functional block diagram of a dynamically adaptable data acquisition system 100, according to an example of the presently disclosed subject matter;

FIG. 2 is a flowchart of a sequence of operations carried out, in accordance with an example of the presently disclosed subject matter.

### DETAILED DESCRIPTION

In the drawings and descriptions set forth, identical reference numerals indicate those components that are common to different embodiments or configurations. Elements in the drawings are not drawn to scale.

Unless specifically stated otherwise, as apparent from the following discussions, it is appreciated that throughout the specification discussions utilizing terms such as “connecting”, “activating”, “switching”, or the like, include actions and/or processes of a computer that manipulate and/or transform data into other data, said data represented as physical quantities, e.g. such as electronic quantities, and/or said data representing the physical objects.

The terms “processor”, “processing unit”, “computer” or the like should be expansively construed to include any kind of electronic device with data processing circuitry, which includes a computer processor as disclosed herein below (e.g., a Central Processing Unit (CPU), a microprocessor, an electronic circuit, an Integrated Circuit (IC), firmware written for or ported to a specific processor such as digital signal processor (DSP), a microcontroller, a field programmable gate array (FPGA), an application specific integrated circuit (ASIC), etc.) and executes computer instructions (e.g. loaded on a computer memory) which is capable of executing various data processing operations.

As used herein, the phrase “for example,” “such as”, “for instance” and variants thereof describe non-limiting embodiments of the presently disclosed subject matter. Reference in the specification to “one case”, “some cases”, “other cases” or variants thereof means that a particular feature, structure or characteristic described in connection with the embodiment(s) is included in at least one embodiment of the presently disclosed subject matter. Thus the appearance of the phrase “one case”, “some cases”, “other cases” or variants thereof does not necessarily refer to the same embodiment(s).

It is appreciated that certain features of the presently disclosed subject matter, which are, for clarity, described in the context of separate embodiments, may also be provided in combination in a single embodiment. Conversely, various features of the presently disclosed subject matter, which are, for brevity, described in the context of a single embodiment, may also be provided separately or in any suitable sub-combination.

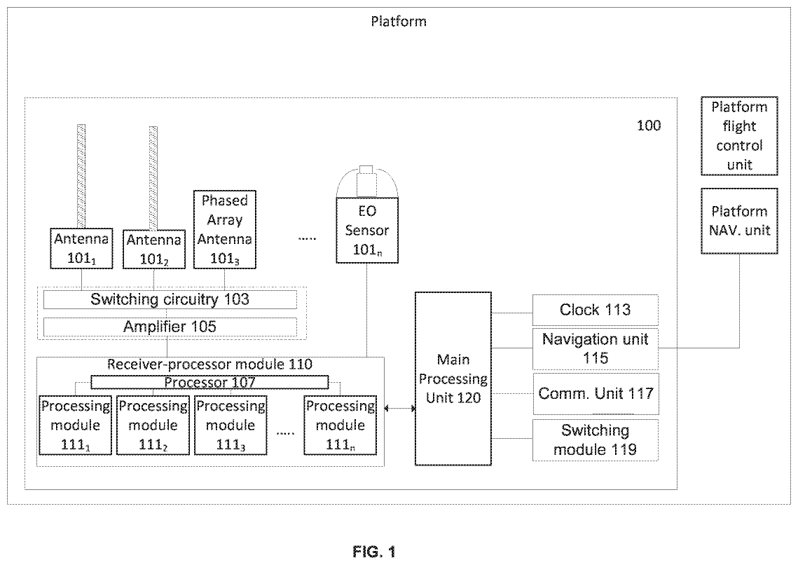

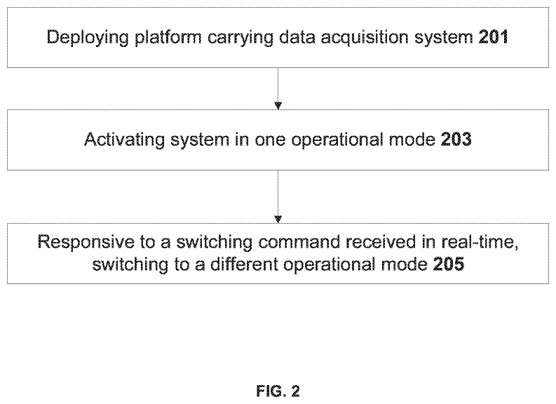

In embodiments of the presently disclosed subject matter, fewer, more and/or different stages than those shown in FIG. 2 may be executed. In embodiments of the presently disclosed subject matter one or more stages illustrated in FIG. 2 may be executed in a different order and/or one or more groups of stages may be executed simultaneously. FIG. 1 illustrate a general schematic of the system architecture in accordance with an embodiment of the presently disclosed subject matter. Functional elements in. FIG. 1 can be made up of any combination of software and hardware and/or firmware that performs the functions as defined and explained herein. Functional elements in. FIG. 1 may be centralized in one location or dispersed over more than one location. In other embodiments of the presently disclosed subject matter, the system may comprise fewer, more, and/or different elements than those shown in. FIG. 1. For example, switching module 119, which is illustrated as a component external to processing module 110 can be, according to an alternative design, be integrated as part of processing module 110.

The term “platform” is used herein to include both manned and unmanned vehicles, including aerial vehicles, ground vehicles, and marine vehicles. Unmanned vehicles (UVs), which, in the past, were predominantly used for military applications, are today becoming increasingly popular in civilian applications. Unmanned vehicles include various types, such as for example Unmanned Aerial Vehicles (UAVs also known as Unmanned Aerial systems or drones), Unmanned Ground Vehicles (UGVs), Unmanned Marine Vehicles (UMVs), etc.

Bearing the above in mind, attention is now drawn to FIG. 1 showing a block diagram schematically illustrating a system 100, according to an example of the presently disclosed subject matter. System 100 comprises a main processing unit (or computer) 120 configured and operable to control and monitor the operation of the system. System 100 further comprises two or more antennas 101₁₋ₙ, each antenna configured to collect (receive) and in some cases also transmit a specific type of data. Antennas 101₁₋ₙ include for example:
One or more antennas of different types, each antenna operating in a different frequency range.
RADAR antenna, for example, a small phased array comprising transmitting and receiving elements and weighing for example a few single kilograms. The RADAR can be for example a synthetic aperture RADAR configured to implement automatic ground moving target indication (GMTI). System 100 can also include an electro optic (EO) sensing device such as a visible/IR camera.

As mentioned above different SIGINT applications such as COMMINT and ELINT seek to intercept different types of transmitted data and accordingly each requires a different antenna adapted for operating in a desired frequency band.

Notably, according to examples of the presently disclosed subject matter, the antenna which are used are wide band antennas (e.g. ultra-wide), which are different than the antennas commonly used for these purposes. For example, an antenna with a 2-12 Gigahertz transmission frequency range can be used instead of a 8-10 Gigahertz antenna. Wide band antennas allow to use the same antenna for operating (e.g. intercepting signals) in a wide range of frequencies and thereby reduce the number of antennas and the overall weight and size of the system.

Wide band antennas are less optimal for communication in a specific frequency over large distances as they are characterized by low gain compared to narrow-band directional antennas. However, using antennas with lower gain (e.g. around 0 dB) enables to use corresponding low power amplifiers (e.g. 10 watt or less), which weigh less than high power amplifiers and thus help to further reduce the overall weight and size of system 100. According to some examples, antennas 101₁₋ₙ can include Omni transmission/reception antennas covering frequency range of 0.1 to 18 Ghz as well as GMTI radar phased array antenna can be used.

As explained in more details below, the presently disclosed subject matter also includes a new operational paradigm, which is based on reduced operating range between the platform and the target entity as a result low gain antennas can be used. According to this paradigm system 100 is positioned at a close distance from the target (emitting) entity during operation. For example, an unmanned aerial platform (also known as UAV, UAS or drone), carrying system 100 operates at closer range (e.g. a few single kilometers rather than tens to hundreds of kilometers) from the target entity. This approach allows to detect the signals which are transmitted by the target entity, in spite of the low gain antenna and wide band receiving function low power amplifiers, which are installed in system 100. This approach also enables jamming of ground communication and radar systems that are in the close range, in spite of the low power amplifier and the low gain antennas.

Reverting to FIG. 1, it further shows switching circuitry 103 (including for example various digital switches) and amplifier 105, which are operatively connected to antennas 101₁₋ₙ and to receiver-processor module 110. Receiver-process 110 can be configured as a multi-function wide band digital receiver/processor having the capability to operate in an ultra-wide frequency range, receive and process various types of data including, ELINT and COMINT data. Receiver-process 110 is also capable of generating signals to be transmitted including for example jamming signals, for jamming communication and RADAR systems

According to some examples, receiver-processor module 110 comprises one or more computer processors 107 operatively connected to a plurality of processing modules 111₁₋ₙ, each module comprises dedicated software (or firmware) specifically configured for enabling processing of a certain type of data. Receiver-processor module 110 can in some cases be designed as a single component (in some cases a single card (e.g. PCB), but this is not necessary and in other cases more than one card (e.g. PCB) are used), which comprises hardware elements needed for executing processing of data signals received from the different antennas and which are shared by the different processing channels. According to some examples, switching circuitry 103 and amplifier 105 can be configured as a single component, however this is not always necessary.

Switching circuitry 103 is configured and operable to switch between connections connecting between antenna 101₁₋ₙ and amplifier 105 and receiver-processor module 110. By switching between connections, a processing channel leading between a certain antenna, configured for collecting a certain type of data, and a respective processing circuitry configured for processing the same type of data is selected. Thus, switching enables to select a desired operational mode, from a plurality of available operational modes, each operational mode designated for processing a certain type of data, and thereby cause system 100 to implement a certain type of data acquisition system.

For example, assuming antenna 101₁ is a COMINT antenna (characterized by an appropriate frequency band including data links) and processing module 111₁ is configured for processing COMINT data while antenna 101₂ is an ELINT antenna (characterized by an appropriate frequency band e.g. 18 GHz) and processing module 111₂ is configured for processing ELINT data, switching circuitry 103 connects antenna 101₁ with processing module 111₁ in order to operate system 100 as a COMINT data acquisition system or alternatively connects antenna 101₂ with processing module 111₂ in order to operate system 100 as a ELINT data acquisition system.

Notably, EO sensor can be directly connected to receiver-processor module 110. A processing module dedicated for processing EO data can include for example an image processor configured to execute image processing algorithms and possibly additional software or firmware such as video motion detection algorithms and object tracking algorithms. As EO sensor does not pass through amplifier 105 it can be operated simultaneously with another antenna.

As mentioned above, in some examples, system 100 also comprises transmission capability which can be used for applications which require signal transmission. For example, a transmission can be used during the operation of a jamming signal aimed to disrupt communication of other target entities. For the RADAR application the phased array antenna is implements the transmission and reception basic function. According to some examples, the same components can be used for both signal reception and signal transmission to thereby further reduce size and weight of system 100. For example, signals are generated by receiver-processor 101, amplifier 105 can be used for amplifying both received and transmitted signals. Switching circuitry 103 can be configured and operable to switch between reception (operational) mode and transmission (operational) mode. In reception operational mode, a processing channel connecting an antenna to amplifier 105 and amplifier 105 to a suitable processing module in receiver-processor module 110 is selected by switching circuitry to provide amplification to received signals. In transmission (operational) mode, a processing channel connecting a processing module (configured to generate signals of a certain frequency range) in receiver-processor module 110 to amplifier 105 and amplifier 105 to a suitable antenna is selected by switching circuitry to provide amplified transmitted signals. This architecture and switching enable to use the same amplifier for both transmission and reception of signals and thus reduce the size and weight of system 100.

Receiver-processor module 110 can further comprise an analog to digital converter (implemented for example by an ultrafast sampling devise; not shown) for converting received signals to digital data ready for processing. Switching circuitry 103 can be configured and operable to connect the same A to D converter (front-end) to the respective sensor in accordance with the desired operational mode.

Switching circuitry 103 is responsive to a switching command indicating a desired operational mode. Assuming for example that system 100 is mounted on an unmanned platform (e.g. UAV, UAS, drone, e.g.), switching commands can be received from a remote control unit (e.g. ground control unit—GCU), which is commonly used for controlling the operation of the unmanned vehicle. A switching command can be received over a line of sight or satellite (beyond line of sight) communication link (e.g. via communication unit 117). The switching command can be initiated by an operator (e.g. following deployment of the unmanned system while the drone is in the air) to enable dynamic control over the operational mode of system 100 to thereby dynamically adapt (in real-time) the data collection implemented by system 100 according to changing needs. In some examples, switching command can be initiated by an operator directly communicating with system 100 and not through a control unit. For example, a personal located on the ground within the operating area of the data acquisition system may have some ability to control certain operations of system 100. According to further examples, switching command can be received from a central control station configured to manage (e.g. prioritize) commands received from different sources and forward them to system 100.

In some examples, switching can be executed based on predefined switching logic. The switching logic can provide rules defining when switching between different operational modes should occur to thereby enable automatic switching. For example, system 100 can comprise switching module 119 configured for generating switching instructions according to the switching logic, thus allowing autonomous switching between different operational modes. For example, the switching can be time based, where switching between one operational mode to another occurs at a certain time (e.g. based on a predetermined schedule) or after a certain time has lapsed from the previous switching. In another example, switching between operational modes can be location based, where switching between modes is done automatically, depending on the current position of the carrying platform (e.g. based on positioning data obtained from navigation unit 115). Switching logic can be pre-stored in a computer data-storage device in system 100 (e.g. within switching module 119), which can be for example integrated in or otherwise accessible by main processing unit 120. Alternatively or additionally, switching logic can be uploaded (e.g. transmitted from a ground control unit) to system 100 after deployment e.g. while airborne.

Main processing unit 120 can be configured and operable to manage and control the switching and issue the actual switching command to the switching circuitry. To this end, main processing unit 120 is operatively connected to sources providing the switching command data. For example, main processing unit 120, can be operatively connected to communication unit 117 and receive switching commands from a remote control unit or a remote “on the ground” personal. and be configured an operable to generate switching commands to the switching circuitry 103 based on the switching logic.

As mentioned above, in some examples, main processing unit 120, can be also operatively connected to switching module 119 and be configured an operable to generate switching commands to the switching circuitry 103 based on the switching logic.

In some examples, main processing unit 120, can be also operatively connected to navigation unit 115. Navigation unit 115 can include for example INS and GPS units and is configured and operable to determine position of system 100. Navigation unit can be a dedicated unit of system 100 or a navigation unit of a carrying platform (e.g. UAS or drone). The latter configuration is in accord with the general desire of avoiding unnecessary increase to the size and weight of system 100.

System 100 can further comprise an accurate clock 113 operatively connected to main processing unit 120. Accurate clock 113 e.g. an atomic clock, can be added for the purpose of time synchronization between different platforms.

FIG. 2 is a flowchart showing a sequence of operations carried out according to an example of the presently disclosed subject matter. Operations described with reference to FIG. 2, can be executed, for example, with the help of system 100 as described above with reference to FIG. 1.

As mentioned above, system 100 can be mounted on an unmanned or manned mobile platform. According to one example, system 100 is mounted on an unmanned vehicle such as an unmanned aerial system, UAV, or drone. In the following description the term “UAS” is used, however it should be construed as limiting in any way.

At block 201 the UAS takes off and a flies to a target destination where data acquisition (and/or jamming) is desired. According to some examples, responsive to an activation (e.g. switching) command system 100 begins to operate in one of the operational modes (block 203). As explained above, in each operational mode a train of devices are connected to enable acquisition of a specific type of data. Specifically, a processing channel connecting between a first antenna and a respective processing module in receiver-processor module 110, is switched on by the switching circuitry.

According to some examples, while the UAS is airborne, responsive to a switching command, system 100 switches from operating in one operational mode to a different operational mode (block 205). By switching a different processing channel connecting between a second antenna and a respective processing module in receiver-processor module 110 is connected to thereby implement a different type of data acquisition system and collect the corresponding type of data. As mentioned above, in some examples, an EO sensor can operated in any operational mode together with the antenna selected in that mode.

2 examples of UAS deployment as disclosed here include: deployment of more than one UAS in a given area where all deployed UASs operate in the same mode of operation for better performance and/or coverage; and deployment of more than one UAS in a given area where different deployed UASs operate in the different mode of operation to increase operational versatility (obtain different types of data). In some cases, a combination of a plurality of UAS operating the same mode and another plurality operating each in a different mode can be deployed.

By way of example, in one possible operational scenario two or more UASs are deployed over the same area, each carrying data acquisition system 100 as disclosed herein, where a first UAS is operating in COMINT operational mode (operating as COMINT gathering system) and a second UAS is operating in ELINT mode (operating as ELINT gathering system). Assuming COMINT has greater priority, in case the first UAS become inoperable, a switching command is sent to the second UAS instructing to switch from ELINT mode to COMINT mode in place of the first UAS in order to resume COMINT data gathering. According to some examples, such a command can be generated by an operator or by predefined switching logic. In this specific example, switching logic can include instructions for the second UAS to switch to COMINT operational mode in case data indicating that the first UAS has become inoperable is received at the first UAS. The presently disclosed subject matter includes a single data acquisition system capable of switching between different operational modes, where different types of data acquisition is implemented in each mode. The reduced size and weight of the system enables the system to be carried by small mobile platforms. For example, system 100 can be airborne by a low weight UAS characterized by a maximal takeoff weight between 20 to 50 kilograms or according to a more specific example a maximal takeoff weight between 25 to 35 kilograms. One such platform is Bird-Eye 650D, an Israeli Aerospace Industries (IAI) LTD manufactured mini-UAV, characterized by a maximal takeoff weight of 30 kilograms.

The low size and weight of the data acquisition system disclosed herein and the ability to carry such system onboard vehicles of small dimensions helps to reduce the price tag of both the system itself as well as the carrying platform.

In some examples, the data acquired by the data acquisition system can be down linked to the ground in close range Line Of Sight or in close range Line Of Sight to another platform that will use other means of communication in order to link the acquired data to the ground. As mentioned above a new operational paradigm is disclosed herein, where data acquisition is performed from a short distance (e.g. between 1 to 10 kilometers) in order to compensate for the low gain (and thus low Tx/Rx (operational) range) of system 100. A plurality of platforms (e.g. unmanned airborne platform) each carrying a data acquisition system as disclosed herein can be used in order to cover areas which are larger than operational range of a single system. Due to the low cost of life cycle of the system and carrying platform, loss of a platform (e.g. as a result of operating in close proximity to the target entity) is more affordable.

In addition, the use of similar or identical platforms each carrying a data acquisition system with similar or identical capabilities, provides operational redundancy enabling to easily replace an inoperable platform with an operating platform in real-time. Furthermore, the smaller size of the platform reduces its footprint and increases its survivability (e.g. it is characterized by low RADAR cross-section) and its lower energy consumption enables longer operation hours.

According to some examples, the carrying platform includes additional components, including for example collision avoidance system (e.g. to increase survivability during operation of a UAS in crowded air space) and automatic takeoff and landing system (which are not shown in FIG. 1).

It is to be understood that the presently disclosed subject matter is not limited in its application to the details set forth in the description contained herein or illustrated in the drawings. The presently disclosed subject matter is capable of other embodiments and of being practiced and carried out in various ways. Hence, it is to be understood that the phraseology and terminology employed herein are for the purpose of description and should not be regarded as limiting. As such, those skilled in the art will appreciate that the conception upon which this disclosure is based may readily be utilized as a basis for designing other structures, methods, and systems for carrying out the several purposes of the present presently disclosed subject matter.

1. A system, comprising:
a dynamically adaptable multipurpose data acquisition sub-system, comprising:
at least two antennas each of which is configured to receive and/or transmit different type of data signals;
a shared amplifier operatively connected to the at least two antennas and to a shared receiver-processor module, and configured to amplify data signals received by any one of the at least two antennas;
wherein the shared receiver-processor module comprises at least one processor operatively connected to a plurality of different processing modules; each processing module of the plurality of different processing modules is configured and operable to process amplified data received by a respective antenna from the at least two antennas;
a main processing unit configured and operable to control switching executed by a shared switching circuitry;
wherein the shared switching circuitry is configured and operable, responsive to a switching command, received from the main processing unit, to switch between operational modes, wherein in each of the operational modes, a processing channel connecting between a certain processing module in the shared receiver-processor module, the shared amplifier and a respective antenna, is selected for processing amplified data of a certain data type, received by the respective antenna to thereby implement a respective data acquisition system.

2. The system of claim 1, further comprising a mobile platform configured and operable to carry the sub-system to a target destination.

3. The system of claim 2, wherein the mobile platform includes an unmanned aerial platform.

4. The system of claim 3, wherein the unmanned aerial platform weighs between 20 to 50 kilograms.

5. The system of claim 3, wherein the unmanned aerial platform weighs between 25 to 35 kilograms.

6. The system of claim 2, further comprising a control unit; the control unit is configured and operable to control the operation of the system, and wherein the switching command is transmitted over a communication link from the control unit and received by the main processing unit.

7. The system of claim 1, further comprising switching logic, wherein the switching command is autonomously generated based on the switching logic.

8. The system of claim 1, wherein in each processing channel, the respective antenna is connected to the shared amplifier, to thereby enable usage of the same amplifier in all processing modes.

9. The system of claim 1, wherein in each processing channel, the respective antenna is connected to a shared analog to digital converter, to thereby enable usage of the same amplifier in all processing modes.

10. The system of claim 1, wherein the at least two antennas comprise at least three antennas comprising: at least two antennas each of which is configured to operate in a different frequency range, and a phased array RADAR antenna.

11. The system of claim 1, wherein the at least two antennas include at least a first antenna for collecting COMINT data and a second antenna for collecting ELINT data.

12. The system of claim 1, wherein the at least two antennas include at least one antenna characterized by a gain value around 0 dB and power of 10 Watt or less.

13. The system of claim 1, wherein the switching circuitry is configured and operable to switch between reception operational mode and transmission operational mode; wherein in transmission operational mode, a processing channel connecting a processing module in the receiver-processor module to the amplifier and amplifier to a respective antenna is selected by switching circuitry to provide amplified transmitted signals; the processing module is configured and operable to generate signals of a certain frequency range.

14. The system of claim 1, further comprising an electro optic sensor operatively connected to a respective processing module configured and operable to process images captured by the electro optic sensor.

15. A dynamically adaptable multipurpose data acquisition system, comprising:
at least two antennas each of which is configured to receive and/or transmit different type of data signals;
a shared amplifier operatively connected to the at least two antennas and to a shared receiver-processor module, and configured to amplify data signals received by any one of the at least two antennas;
wherein the shared receiver-processor module comprises at least one processor operatively connected to a plurality of different processing modules; each processing module of the plurality of different processing modules is configured and operable to process amplified data received by a respective antenna from the at least two antennas;
a main processing unit configured and operable to control switching executed by a shared switching circuitry;
wherein the shared switching circuitry is configured and operable, responsive to a switching command, received from the main processing unit, to switch between operational modes, wherein in each of the operational modes, a processing channel connecting between a certain processing module in the shared receiver-processor module, the shared amplifier and a respective antenna, is selected for processing amplified data of a certain data type, received by the respective antenna to thereby implement a respective data acquisition system.

16. An unmanned aerial platform, comprising:
a dynamically adaptable multipurpose data acquisition system comprising:
at least two antennas each of which is configured to receive and/or transmit different type of data signals;
a shared amplifier operatively connected to the at least two antennas and to a shared receiver-processor module, and configured to amplify data signals received by any one of the at least two antennas;
the shared receiver-processor module comprises at least one processor operatively connected to a plurality of different processing modules; each processing module of the plurality of different processing modules is configured and operable to process amplified data received by a respective antenna from the at least two antennas;
a main processing unit configured and operable to control switching executed by a shared switching circuitry;
the shared switching circuitry is configured and operable, responsive to a switching command, received from the main processing unit, to switch between operational modes, wherein in each of the operational modes, a processing channel connecting between a certain processing module in the shared receiver-processor module, the shared amplifier and a respective antenna, is selected for processing amplified data of a certain data type, received by the respective antenna to thereby implement a respective data acquisition system.

17. The platform of claim 16 is characterize by a weight between 25 to 30 kilograms.

18. The platform of claim 16, wherein the at least two antennas include at least a first antenna for collecting COMINT data and a second antenna for collecting ELINT data.

19. The platform of claim 16, wherein the at least two antennas further include an antenna of a phased array RADAR.

20. The platform of claim 16, wherein the at least two antennas include at least one antenna characterized by a gain value around 0 dB and power of 10 Watt or less.

21. A method of operating the system of claim 16, the method comprising:
while the unmanned aerial platform is airborne:
operating the system in a first operational mode where a first sensor device is connected to a respective processing module in the processing module to thereby obtain a first type of data;
responsive to a received switching command, operating the switching circuitry for switching to a second operational mode where a second sensor device is connected to a respective processing module in the processing module to thereby obtain a second type of data.
